(19) United States
(12) Patent Application Publication
(10) Pub. No.: US 2005/0205918 A1
(43) Pub. Date: Sep. 22, 2005

(54) Semiconductor device and method for manufacturing the same

(75) Inventor: Hitoshi Abiko, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION

(21) Appl. No.: 11/080,558

(22) Filed: Mar. 16, 2005

(30) Foreign Application Priority Data
Mar. 18, 2004 (JP) 2004-079229

(51) Int. Cl. H01L 27/108

(52) U.S. Cl. 257/303; 438/253

(57) ABSTRACT

A semiconductor device can be stably provided a capacitor inside a lower layer interconnect with a simple process. In the semiconductor device, a lower electrode, an etching stopper film, and a first insulating film are provided on a silicon substrate in this order. A connection plug coming into contact with an upper face of the lower electrode is provided in the first insulating film. A capacitor element is formed upon providing a capacitor film and a metal film disposed in beside the connection plug in this order.

This application is based on Japanese patent application NO. 2004-079229, the content of which is incorporated hereinto by reference.

### BACKGROUND OF THE INVENTION

1. Field of the Invention

The present invention related to a semiconductor device and a method for manufacturing the same.

2. Related Art

A semiconductor device having capacitor elements as for the conventional one is disclosed in the Japanese Laid-Open Patent Publication No. 2000-58781. In the semiconductor device disclosed in the Japanese Laid-Open Patent Publication No. 2000-58781, there is provided a wedge-like conductive projection on a lower electrode. And a capacitor film and an upper electrode are provided on the lower electrode. A capacitor is formed in above and beside the lower layer electrode. By adopting such configuration, it is regarded that capacitance per unit area can be increased.

### SUMMARY OF THE INVENTION

However, the present inventor has examined the related art disclosed in the Japanese Laid-Open Patent Publication No. 2000-58781, and has now found that, there is still room for improvement in respect of the following point. Firstly, in order to obtain structure of the Japanese Laid-Open Patent Publication No. 2000-58781, a process to provide the wedge-like conductive projection in an inter layer insulating film becomes a necessity aside from a process to form connection hole. For this reason, a manufacturing process was complicated. In addition, it was difficult to control height of valley portion formed on an upper face of a dielectric film embedded between the adjacent conductive projections. As a result, it was difficult to control the capacitance of a capacitor.

According to the present invention, there is provided a semiconductor comprising a semiconductor substrate, an insulating film provided on the semiconductor substrate, a first conductor composed of a columnar body provided in the insulating film, a second conductor provided around the first conductor and separated from a side surface of the first conductor, and a capacitor film provided between the first conductor and the second conductor.

In the semiconductor device, there are formed the capacitor film and the second conductor around the columnar body in this order from the center of the columnar body toward outer portion, with the columnar body provided in the insulating film as the first conductor. For this reason, in the configuration, the capacitor element composed of the first conductor, the capacitor film and the second conductor is provided in the insulating film. Consequently, configuration which makes it possible to provide the capacitor element with simple configuration and a high yield is realized.

In the present specification, the columnar body indicates a shape, which has proper extent at an upper face and a bottom face. The columnar body may suitably be a cylinder, an elliptical cylinder or a square column in which area of the upper face and area of the bottom face are approximately identical with each other. Further, the columnar body may suitably be a shape of frustum of circular cone, frustum of elliptical cone, or frustum of pyramid with no leading end on an upper face. Further, the columnar body may suitably be a trench shape stretching in one direction.

In the semiconductor device of the present invention, it may be suitable to adopt configuration in which the second conductor may be composed of a conductive film embedded in the insulating film. Thereby, it is possible to realize configuration, which makes it possible to manufacture the semiconductor device with a simple manufacturing process. In addition, it may be suitable to surely keep the charge between the second conductor and the first conductor.

In the semiconductor device of the present invention, it may be also suitable that the second conductor is provided on the etching stopper film, and the second conductor has a flat bottom face. Thereby, it is possible to realize configuration with excellent controllability on the film thickness of the capacitor film. As a result, it is possible to realize configuration with excellent controllability on the capacitance.

In the semiconductor device of the present invention, it may be also suitable that the etching stopper film is formed so as to cover a side wall in a vicinity of the bottom portion of the first conductor. Thereby, it is possible to realize configuration in which the side wall in the vicinity of the bottom portion of the first conductor is supported with the etching stopper film. As a result, it is possible to realize configuration with further excellent manufacturing stability.

In the semiconductor device of the present invention, it may be also suitable that the film thickness of the capacitor film is approximately uniform. Thereby, it is possible to suppress variation of the capacitance of the capacitor element composed of the first conductor, the capacitor film and the second conductor.

In the semiconductor device of the present invention, it may be also suitable that the first conductor and the second conductor are formed with the same material. Thereby, it is possible to realize configuration which makes it possible to manufacture the semiconductor device with simple manufacturing process.

In the semiconductor device of the present invention, it may be also suitable that the first conductor has a cylinder shape. Thereby, it is possible to improve controllability of the capacitance of the capacitor element composed of the first conductor, the capacitor film and the second conductor. In addition, it is possible to realize configuration which makes it possible to simultaneously manufacture the first conductor at the time the connection plug is formed in the insulating film. As a result, it is possible to realize configuration which makes it possible to manufacture the semiconductor device with more simple process.

In the semiconductor device of the present invention, it may be also suitable that an upper face of the first conductor and an upper face of the second conductor reside in the same plane. This configuration is one where the first conductor and the second conductor are positioned at the same level, therefore, it is possible to realize configuration which makes it possible to simultaneously manufacture the capacitor element in forming the first conductor. In addition, it is possible to utilize the entire side surface of the first conductor as for the capacitor element. As a result, it is possible to secure the sufficient capacitance.

In the semiconductor device of the present invention, it may be suitable that an upper face of the second conductor is positioned under an upper face of the first conductor on an end portion of the semiconductor conductor. Namely, it is a recess configuration where an upper edge portion of the second conductor recedes downward. As a result, it is possible to prevent leakage between adjacent the first conductor and the second conductor.

In the semiconductor device of the present invention, plural capacitor elements composed of the first conductor, the second conductor and the capacitor film may be provided in the insulating film. Thereby, it is possible to secure further sufficient capacitance. In addition, it is possible to realize configuration in which an unused region in the insulating film is further effectively used.

In the semiconductor device of the present invention, it may be also suitable that there is provided a lower electrode provided in such way as to come into contact with a bottom portion of a plurality of the first conductors. Thereby, it is possible to realize configuration, which makes it possible to render the plurality of the first conductors into the same potential.

According to the present invention, there is provided a method for manufacturing a semiconductor device, comprising forming a lower electrode on a semiconductor substrate, forming an insulating film on the lower electrode, forming a columnar connection hole, which reaches an upper face of the lower electrode while selectively removing the insulating film, forming a first metal film so as to embed the connection hole, obtaining a first conductor while removing the metal film formed on outside the connection hole, forming a concave portion while removing the insulating film around the first conductor and exposing at least a part of a side wall of the first conductor, forming a capacitor film covering the side wall so as to embed the part of the concave portion, forming a second metal film so as to embed the concave portion after forming the capacitor film, and obtaining a second conductor while removing the second metal film formed on outside the concave portion.

According to the method for manufacturing the semiconductor device of the present invention, it is possible to form the capacitor element composed of the first conductor, the capacitor film and the second conductor in the insulating film with simple process and high yield.

According to the present invention, there is provided a method for manufacturing a semiconductor device, comprising: forming a transistor with gate electrode and a diffusion region at a first element region on a semiconductor substrate; forming a lower electrode at a second element region on the semiconductor substrate; forming an insulating film to cover the transistor and the lower electrode; forming a first connection hole and a second connection hole in the insulating film simultaneously, the first connection hole exposing the diffusion region therein and the second connection hole exposing the lower electrode therein; filling the first connection hole and the second connection hole with a first conductive material simultaneously to form a connection plug on the diffusion region and a first conductor at the second element region; forming a concave portion while removing the insulating film around the first conductor to expose at least a part of a side wall of the first conductor; forming a capacitor film covering the side wall; forming a second conductive material on the capacitor film to fill the concave portion and to form a second conductor composing a capacitor together with the lower electrode, the first conductor and the capacitor film.

According to the method for manufacturing the semiconductor device of the present invention, it is possible to form the capacitor element composed of the first conductor, the capacitor film and the second conductor in the insulating film with constituting the same layer as the transistor. In addition, it is possible to form the first conductor simultaneously in the process of forming the connection plug in the insulating film. Thereby, it is possible to stably manufacture the capacitor element in the simple process.

In the method for manufacturing the semiconductor device of the present invention, forming an etching stopper film on the lower electrode may suitably be included, after forming the lower electrode and before forming the insulating film. Thereby, it is possible to form the capacitor film, which is provided in such a way as to come into contact with the bottom face of the first conductor and the bottom face of the second conductor, into flat. As a result, it is possible to further surely control the capacitance of the capacitor element manufactured. In addition, also when providing a plurality of capacitor elements, it is possible to stably manufacture the semiconductor device with a high yield, while suppressing variation of the capacitance among the capacitor elements.

In the method for manufacturing the semiconductor device of the present invention, it may be also suitable that the first metal film and the second metal film are copper containing metal films. As a result, it is possible to surely form the capacitor element in the semiconductor device with simple process.

As described above, according to the present invention, upon providing a first conductor composed of a columnar body, a second conductor provided around the first conductor and separated from a side surface of the first conductor, and a capacitor film provided between the first conductor and the second conductor in the insulating film, technique to stably provide a capacitor in the lower layer interconnect with a simple process is obtained.

### BRIEF DESCRIPTION OF THE DRAWINGS

The above and other objects, advantages and features of the present invention will be more apparent from the following description taken in conjunction with the accompanying drawings, in which:

FIG. 1 is a cross-sectional view schematically showing configuration of a semiconductor device according to the present embodiment;

FIGS. 2A to 2C are cross-sectional views illustrating a manufacturing process of the semiconductor device of FIG. 1;

FIGS. 3D to 3F are cross-sectional views illustrating the manufacturing process of the semiconductor device of FIG. 1;

FIG. 4G is a cross-sectional view and a plan view illustrating the manufacturing process of the semiconductor device of FIG. 1;

FIGS. 5H and 5I are cross-sectional views illustrating the manufacturing process of the semiconductor device of FIG. 1;

FIG. 6 is a cross-sectional view and plan view schematically showing a capacitor element provided on the semiconductor device according to the present embodiment;

FIGS. 7A and 7B are views exemplifying electrical connecting method between a conductor constituting the capacitor element of the semiconductor device and an outside semiconductor device of FIG. 1;

FIG. 8 is a cross-sectional view schematically showing configuration of the semiconductor device according to the present embodiment; and

FIGS. 9A to 9C are cross-sectional views illustrating a manufacturing process of the semiconductor device of FIG. 8.

### DETAILED DESCRIPTION OF THE INVENTION

The invention will now be described herein with reference to illustrative embodiments. Those skilled in the art will recognize that many alternative embodiments can be accomplished using the teachings of the present invention and that the invention is not limited to the embodiments illustrated for explanatory purposed.

Hereinafter, there will be illustrated embodiments of the present invention with reference to the drawings. In the whole drawings, the same symbol is attached to a common component, and detailed description will be omitted appropriately.

### First Embodiment

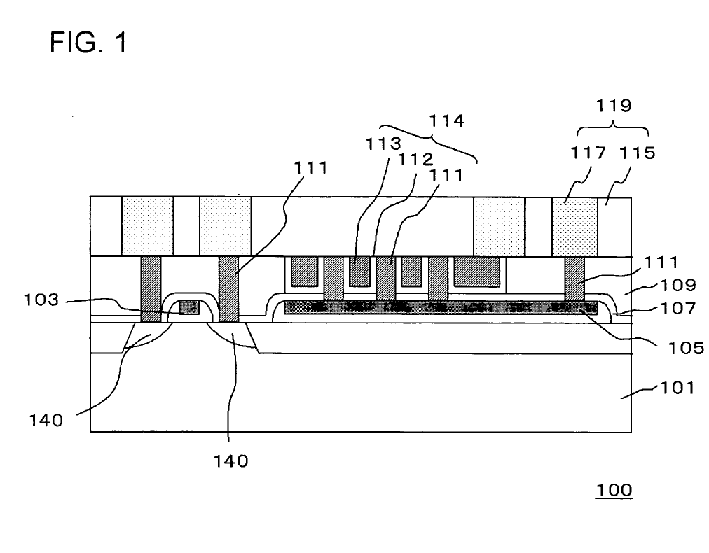

FIG. 1 is a cross-sectional view schematically showing configuration of the semiconductor device according to the present embodiment. In the semiconductor device 100 shown in FIG. 1, a MOS transistor composed of a gate electrode 103, a diffusion layer 140 or the like, and a lower electrode 105 are formed on a silicon substrate 101.

A first insulating film 109 is formed so as to embed the MOS transistor and the lower electrode 105. An etching stopper film 107 coming into contact with an upper face of the lower electrode 105 and a cylindical connection plug 111 are respectively provided in the first insulating film 109. The etching stopper film 107 is formed so as to cover a side wall in the vicinity of a bottom portion of the etching stopper film 107. In addition, also a connection plug 111 connecting to the diffusion layer 140 is provided on the first insulating film 109.

Above the etching stopper film 107, a capacitor film 112, which has a flat bottom face and an annular shaped upper cross section, and a metal film 113 are embedded in the first insulating film 109 in this order from under the first insulating film 109. Thickness of the capacitor film 112 is approximately uniform. In addition, an upper face of the connection plug 111 and an upper face of the metal film 113 form the same flat surface, which also agrees with an upper face of the first insulating film 109.

The capacitor element 114 is composed of the connection plug 111, the metal film 113 provided separately from a side face of the connection plug 111, and the capacitor film 112 provided between the capacitor element 114 and the metal film 113. The connection plug 111 is insulated from the metal film 113 by the capacitor film 112. The connection plug 111 and the metal film 113 may be made with the same material, and also may be made with different materials. Hereafter, there will be exemplified the case where both the connection plug 111 and the metal film 113 are Cu film.

Above the layer including these metal films, a first interconnect layer 119 in which an interconnect 117 is provided in a second insulating film 115 is formed with layered structure. FIG. 1 shows the layer up to the first interconnect layer 119, and the layer provided with a metal film is formed above the first interconnect layer 119, thus multilayered semiconductor device is constituted.

Further, it may be suitable that the capacitor element 114 described later is provided on which layer of the semiconductor device 100. In addition, it is not shown in FIG. 1, the metal film 113 comes into contact with the interconnect 117 or other conductor at a predetermined position of an upper face of the metal film 113, so that the metal film 113 electrically connected to the upper layer surely.

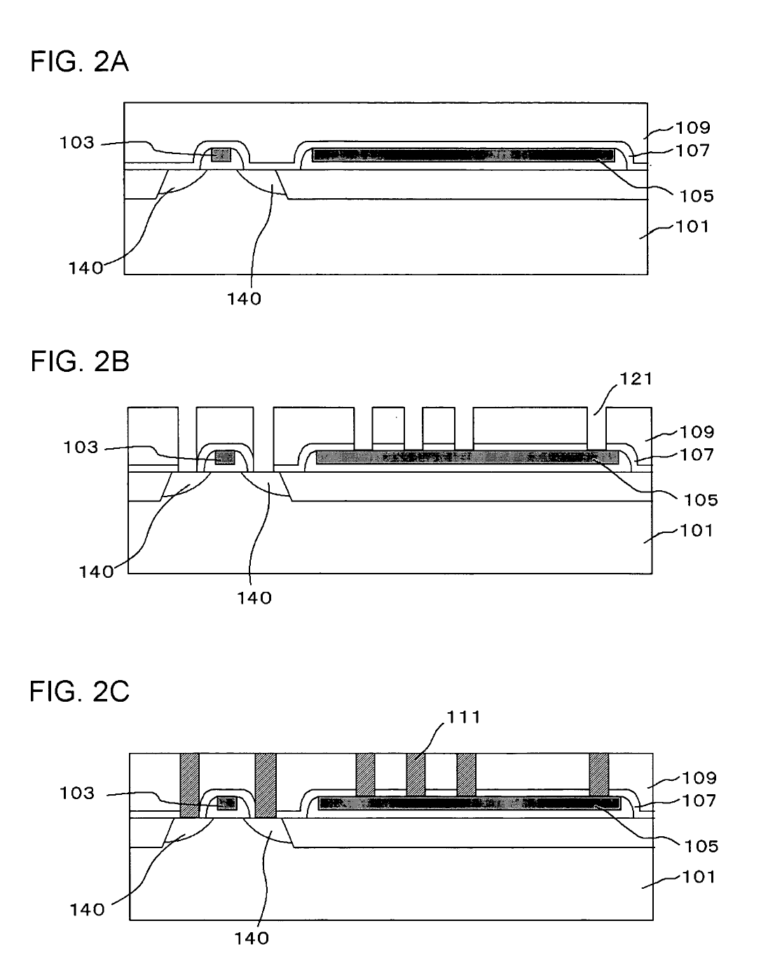

Next, there will be illustrated a method for manufacturing the semiconductor device 100. FIGS. 2A to 2C, FIGS. 3D to 3F, FIG. 4G and FIGS. 5H to 5I are cross-sectional views showing a manufacturing process of the semiconductor device 100.

First, predetermined elements such as the MOS transistor, the lower electrode 105 or the like are formed on the silicon substrate 101. After that, the etching stopper film 107 and the first insulating film 109 are formed in this order on the entire upper surface of the silicon substrate 101 (FIG. 2A).

At this time, as for the etching stopper film 107, for instance, an SiCN film of 50 nm is formed by the plasma CVD technique. In addition, as for the first insulating film 109, for instance, an SiO₂ film of 100 nm is formed by the plasma CVD technique. Or as for the first insulating film 109, it may suitably be formed the layered film in such a way that L-Ox™ film of 300 nm to be a low dielectric constant interlayer insulating film is formed by an application technique, and SiO₂ film of 100 nm is formed on an upper face of the L-Ox™ film.

Next, a position to provide the connection plug 111 is opened while performing the dry etching of the first insulating film 109. Then an etching back of the etching stopper film 107 by the dry etching is performed, to open a conductive face for the lower electrode 105. A wet removing is performed for an etching residue removing to form a connection hole 121 (FIG. 2B).

Next, W film (not shown in the drawings) with film thickness of 30 nm is formed by the sputtering technique as a barrier metal, subsequently, Cu film (not shown in the drawings) with film thickness of 100 nm is formed on the W film by the sputtering method. After that, Cu film with film thickness of 700 nm is formed by an electroplating technique, followed by embedding the connection hole 121, subsequently, heat treatment in an atmosphere of N₂, for 30 minutes at 400 degree centigrade for growth of copper grain is performed. Then, the Cu film and the W film on the first insulating film 109 are removed by CMP (Chemical Mechanical Polishing), and the connection plug 111 is formed via oxalic acid treatment and pure-water rinsing (FIG. 2C). Further, it may be suitable that surface treatment with anticorrosive agent is performed next to the process. In such a way as above, oxidation of Cu surface is prevented.

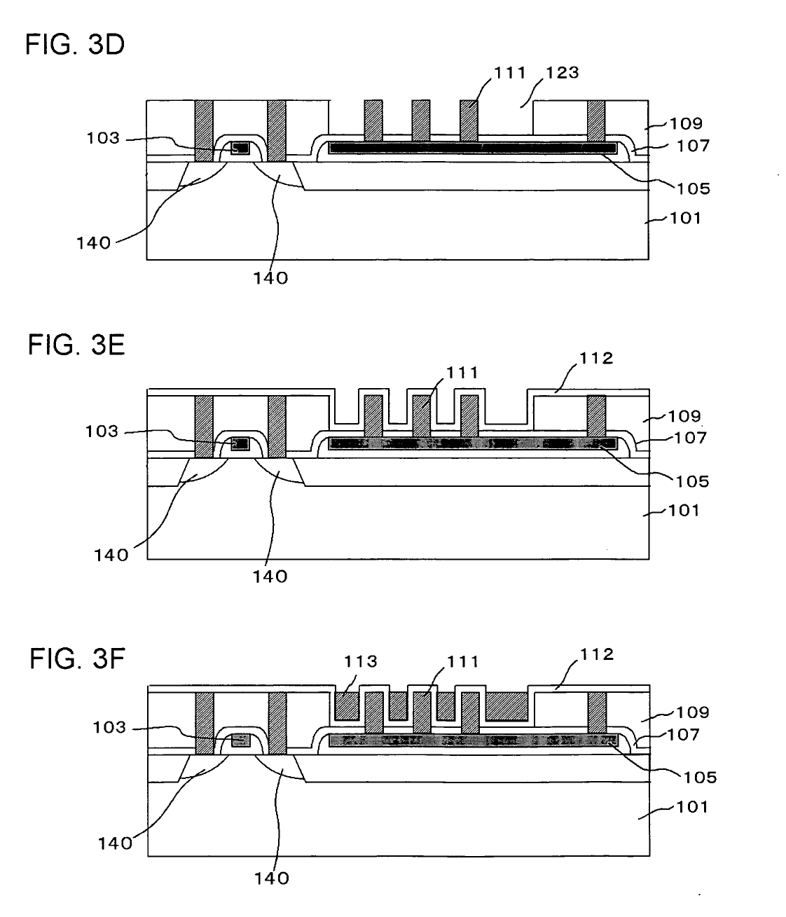

Next, an antireflection film and a photoresist are applied on the first insulating film 109 in this order to form a resist pattern for causing outer periphery of a side face of the connection plug 111 to open using the photolithography technique. As for the photoresist, a chemically amplified resist is used suitably, for instance, a positive resist may be used. Then, an opening 123 to form the capacitor film 112 of the capacitor element 114 is formed while performing an etching of the first insulating film 109 from the resist pattern due to dry etching technique (FIG. 3D). At this time, the etching stops at above the etching stopper film 107, because the etching stopper film 107 is formed under the first insulating film 109, thus a bottom face of the opening 123 is formed into a flat face.

Then, the capacitor film 112 is formed on the entire upper surface of the silicon substrate 101 (FIG. 3E). The capacitor film 112 is formed so as to cover an exposed face of the connection plug 111 and to embed a part of the opening 123. For instance, SiN is used as for the material of the capacitor film 112. In addition, it may be suitable that a high dielectric constant film (high-k film) such as HfO₄, ZrO₄ or the like may be used. The capacitor film 112 is formed by, for instance, a CVD technique, or ALD method (Atomic Layer Deposition Method) or the like. In addition, although the thickness of the capacitor film 112 can be set appropriately depending on the capacitance of the capacitor element 114, it may be set to, for instance, not less than 1 nm to not more than 500 nm.

Next, an antireflection film and a photoresist are applied on the capacitor film 112, followed by forming the resist pattern to open above the opening 123 while using the photolithography technique. Then, like the formation of the connection plug 111, a barrier metal film and a Cu film are formed with layered structure inside the opening 123, to embed the opening 123 with the Cu film. Then, the metal film 113 is formed via the oxalic acid treatment and the pure water rinsing, while removing the Cu film and the barrier metal film on the first insulating film 109 by the CMP (FIG. 3F).

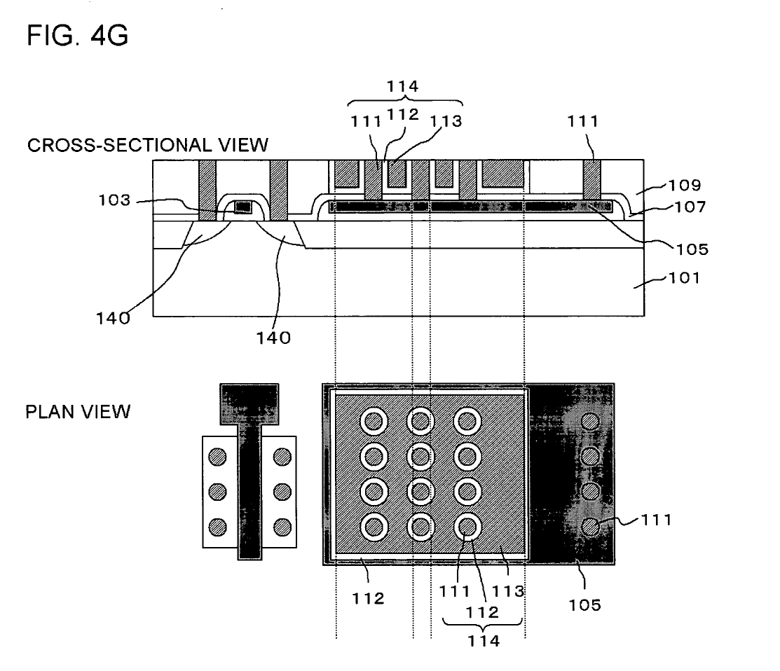

Further, a layer in which the first insulating film 109, the upper face of the connection plug 111 and the metal film 113 are positioned in the same plane is formed upon removing the capacitor film 112 provided on the first insulating film 109 with the dry etching (FIG. 4G).

It should be noted that, in FIG. 4G, the upper drawing is a cross-sectional view, and the lower drawing is a plan view. As shown in these drawings, in the semiconductor device 100, there are provided the capacitor film 112, and the metal film 113 in this order from outside the side wall of the connection plug 111, therefore, a plurality of the capacitor elements 114 are formed with these components. The capacitor element 114 is integrated inside the flat face, and the metal film 113 is formed continuously and integrally, resulting in configuration in which plural capacitor elements 114 share the metal film 113.

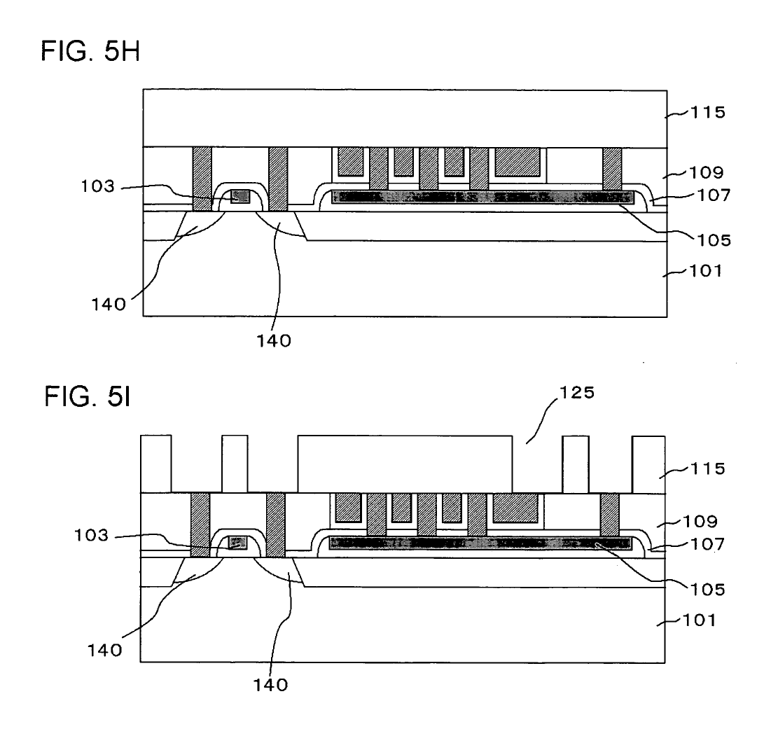

Next, a second insulating film 115 with film thickness of 300 nm to coat the entire upper surface of the silicon substrate 101 is formed (FIG. 5H). The second insulating film 115 can be set to the low dielectric constant film, such as, for instance, L-Ox™ film or the like. At this time, it may be suitable that a SiCN film of Cu diffusion preventing film is provided above the first insulating film 109. In addition, it may be suitable that the SiO₂ film with film thickness of 100 nm is formed above the low dielectric constant film. Next, the antireflection film and the photoresist are applied on the entire upper surface of the silicon substrate 101, followed by forming a interconnect trench resist pattern while using the photolithography technique. Then, an opening 125 to manufacture the interconnect 117 is formed while etching the second insulating film 115 with the photoresist as the mask. Next, the photoresist and the antireflection film are stripped by an ashing (FIG. 5I).

After that, by using the sputtering technique, a W film (not shown in the drawings) with film thickness of 30 nm as for the barrier metal film is formed, followed by forming a Cu film (not shown in the drawings) with film thickness of 100 nm for seeds above the W film. Next, Cu film with film thickness of 700 nm is formed by the electroplating technique, followed by forming a metal film becoming the interconnect 117 by the CMP. After that, like the formation condition of the connection plug 111 and the metal film 113, the Cu film and the barrier metal film above the second insulating film 115 are removed, thus the interconnect 117 is formed via the oxalic acid treatment and the pure water rinsing. In such a way as above, the semiconductor device 100 shown in FIG. 1 is obtained.

In the present embodiment, although there is no limitation in the method for electrically connecting the connection plug 111 or the metal film 113 to outside the semiconductor device, for instance, it becomes possible to electrically connect the connection plug 111 side to outside the semiconductor device 100 upon providing a drawn-out interconnect to draw out the lower electrode 105 above the semiconductor device 100 on respective layers. In addition, the electrical connection between the metal film 113 side and outside the semiconductor device 100 can be performed by providing a connecting metal plug to come into contact with an arbitral position on an upper face of the metal film 113. At this time, as shown in FIG. 4G, the metal film 113 is formed continuously and integrally as the conductor of the plurality of capacitor elements 114, therefore, this makes it possible to connect the plurality of capacitor elements 114 in parallel and to control the plurality of capacitor elements 114 into the same potential, upon conducting connection to one arbitral position of the upper face of the metal film 113. In addition, it is possible to apply the same voltage simultaneously to the plurality of capacitor elements 114. For this reason, it is possible to suppress variation of capacitance between the pluralities of capacitor elements 114.

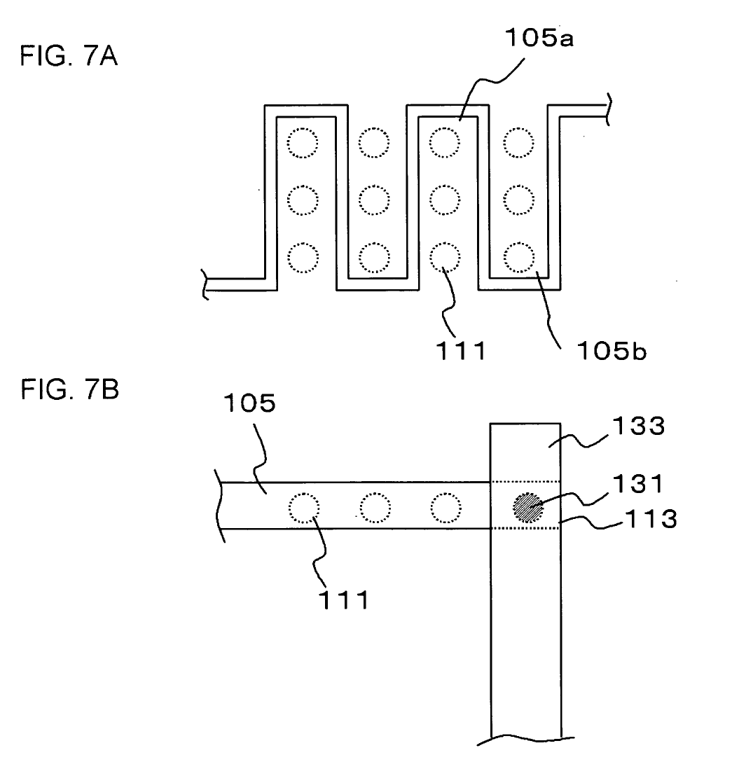

In addition, although it is not shown in FIG. 1, for instance, an electrical connection can be obtained from the connection plug 111 and the metal film 113 with a method shown in FIGS. 7A and 7B. FIGS. 7A and 7B are views illustrating one example of a method for electrically connecting outside the semiconductor device 100 to the conductor constituting the capacitor element 114 of the semiconductor device 100 shown in FIG. 1.

FIG. 7A is a view showing a shape of the lower electrode 105. In FIG. 7A, the lower electrode 105 is constituted of a combination of two of a comb-toothed electrode 105a and a comb-toothed electrode 105b. By forming the lower electrode 105 into such shape, it is possible to electrically connect the connection plug 111 of the plurality of capacitor elements 114 to outside the semiconductor device. In addition, this makes it possible to respectively connect the plurality of connection plugs 111 connected to the comb-toothed electrode 105a and the plurality of connection plugs 111 connected to the comb-toothed electrode 105b in parallel, and to respectively set them into the same potential.

In addition, FIG. 7B is an upper plan view showing one example of a method for electrically connecting the metal film 113 to outside the semiconductor device. There is provided a drawn-out plug 131 above the metal film 113, which is connected to an upper interconnect 133. At this time, there are orthogonally provided the lower electrode 105 connected to the connection plug 111 and the upper interconnect 133. Even such configuration is adopted; it is possible to electrically connect two conductors constituting the capacitor element 114 to outside the semiconductor device.

Successively, effects of the semiconductor device 100 shown in FIG. 1 will be illustrated.

In the semiconductor device 100, the connection plug 111 comes into contact with one side of the capacitor film 112 and the metal film 113 comes into contact with the other side of the capacitor film 112; that is, the capacitor element 114 is formed by the connection plug 111 and the metal film 113 disposed oppositely, and the capacitor film 112 provided between the connection plug 111 and the metal film 113. In order to make the connection plug 111 a component of the capacitor element 114, there is adopted the configuration in which it is possible to form the capacitor element 114 during a manufacturing process of the connection plug 111. For this reason, there is adopted configuration in which it is possible to manufacture it with simple manufacturing process. In addition, the configuration is a configuration in which it is possible to stably manufacture it with high yield.

In addition, the capacitor element 114 is formed within the same layer with the connection plug 111; therefore, configuration of the interconnect 117 is not limited depending on the capacitor element 114. Owing to this, it is possible to cope with various element constitutions, while widening width of selection of the shape of the interconnect 117. In addition, the upper face of the first insulating film 109 and the upper face of the capacitor element 114 become approximately the same face; therefore, it is possible to suppress variation of the shape of the plurality of capacitor elements 114. For this reason, it is possible to suppress variation of capacitance among the plurality of capacitor elements 114.

In addition, the capacitor element 114 and a transistor are formed into the same layer. For this reason, it is possible to dispose the capacitor element 114, while effectively utilizing space within transistor formed layer. In addition, the connection plug 111 connecting to the diffusion layer 140 of the transistor and the connection plug 111 constituting the capacitor element 114 are made with the same material, therefore, it is possible to realize configuration which makes it possible to manufacture them in the same process.

In addition, by making the connection plug 111 a columnar body, it is possible to realize configuration in which manufacturing stability is high as compared with the configuration the connection plug is made the pyramides body. In addition, it is possible to set the height of the connection plug 111 to approximately constant by making the connection plug the columnar body. For this reason, it is possible to further improve the manufacturing stability, and it is possible to reduce variation of capacitance of the capacitor element 114. In addition, by making the connection plug 111 the columnar body, it is possible to make its upper face a flat face. For this reason, control of film thickness of the capacitor film 112 formed above the connection plug 111 becomes easy. In addition, it is possible to make the film thickness approximately constant while reducing variation of the film thickness. Consequently, it is possible to further reduce the variation of the capacitance among the plurality of the capacitor elements 114.

In addition, the capacitor film 112 is provided across the entire side face of the connection plug 111, so that it is possible to secure the capacitance sufficiently. Further, the metal film 113 is provided so as to cover the periphery of the connection plug 111, resulting in configuration where it is possible to further suitably secure the capacitance.

In addition, the etching stopper film 107 is provided on the first insulating film 109; therefore, when forming the opening 123 by the etching, it is possible to render its bottom face into a flat surface. For this reason, it is possible to render the bottom face of the capacitor film 112 and the metal film 113 into the flat surface. Consequently, even inside the opening 123 in which film thickness variation is easy to occur, this makes it possible to improve controllability of the film thickness of the capacitor film 112 and to render the film thickness into approximately constant. For this reason, it is possible to suppress the variation of the capacitance of the capacitor element 114.

In addition, the side wall of the connection plug 111 is covered with the etching stopper film 107 in the vicinity of bottom of the connection plug 111. For this reason, it is suppressed that the connection plug 111 is upset or inclined during the manufacturing process because the connection plug 111 is supported by the etching stopper film 107. Consequently, the semiconductor device 100 has configuration that is excellent in manufacturing stability.

In addition, in the semiconductor device 100, it is possible to integrate the plurality of the capacitor elements 114 on the lower layer of the first interconnect layer 119. Since it is possible to dispose the plurality of the capacitor elements 114 into array shape, it is not necessary for the layer of the capacitor elements 114 to provide independently, so that it is possible to provide the capacitor elements 114 while effectively utilizing spaces within the layer. The semiconductor device 100 can be thinned. In addition, it is possible to sufficiently secure necessary capacitance.

In addition, the metal film 113 is formed continuously and integrally, therefore, the plurality of the capacitor elements 114 share the metal film 113 (FIG. 4G). For this reason, the resultant configuration makes it easy to connect to the plurality of the capacitor elements 114 in parallel, and to set the plurality of the metal films 113 into the same potential. In addition, it is possible to apply voltage to the plurality of the metal films 113 simultaneously. For this reason, even it is miniature configuration, it is possible to secure large capacitance. In addition, all of the pluralities of connection plugs 111 constituting the capacitor elements 114 are electrically connected to the lower electrode 105; therefore, it is possible to make these connection plugs 111 the same potential. In addition, it is possible to apply the same voltage to the plurality of the connection plugs 111 simultaneously.

It should be noted that, in the semiconductor device described in the Japanese Laid-Open Patent Publication No. 2000-58781, there is adopted configuration in which the high dielectric constant film is formed between the wedge-shaped conductive projections. In the configuration, it is feared that the element life deteriorates caused by electric field concentration to a leading end. In addition, since it is difficult to control height of the high dielectric constant film embedded between the conductive projections, variation of the capacitance of the capacitor element is easy to occur. On the other hand, in the semiconductor device 100 according to the present embodiment, the connection plug 111 has appropriate areas at upper face and a bottom face, and is formed into a columnar body having no leading end. For this reason, it is possible to avoid the local electric field concentration in the connection plug 111. In addition, it is possible to realize configuration in which defective film formation of the capacitor film 112 coating the side face of the connection plug 111 is suitably suppressed.

In addition, the configuration of the Japanese Laid-Open Patent Publication No. 2000-58781 necessitates manufacturing process manufacturing the wedge-like conductive projection in addition to the process providing the connection hole, so that the manufacturing process has been complicated. On the contrary, in the semiconductor device 100 according to the present embodiment, since the connection plug 111 with shape of columnar body is set to constituent components of the capacitor element 114, the capacitor element 114 can be obtained simultaneously with the manufacturing process of the connection plug 111. For this reason, the manufacturing process is simplified.

In addition, in the configuration of the Japanese Laid-Open Patent Publication No. 2000-58781, it is necessary to provide plural wedge-like conductive projections, consequently, it was feared that the conductive projections were upset or inclined during the manufacturing process. On the contrary, in the semiconductor device 100 according to the present embodiment, the connection plug 111 is supported by the etching stopper film 107 in the vicinity of the bottom of the connection plug 111; therefore, formation defect of the connection plug 111 is suppressed suitably. Owing to this, it is possible to stably obtain the semiconductor device 100 that is excellent in manufacturing stability.

In addition, the semiconductor device 100 according to the present embodiment has the etching stopper film 107, which is not provided for the semiconductor device of the Japanese Laid-Open Patent Publication No. 2000-58781. For this reason, this makes it possible to flatten the bottom face of the opening 123 formed between adjacent connection plugs 111. Consequently, it is possible to make the film thickness of the capacitor film 112 approximately constant. For this reason, it is possible to suppress variation of the capacitance of the capacitor elements 114.

It should be noted that, in the semiconductor device according to the present embodiment, the number and the shape of the connection plug 111 and the capacitor element 114 are not limited to the shape shown in FIG. 1 and FIG. 4G, thus it is possible to adopt various configurations.

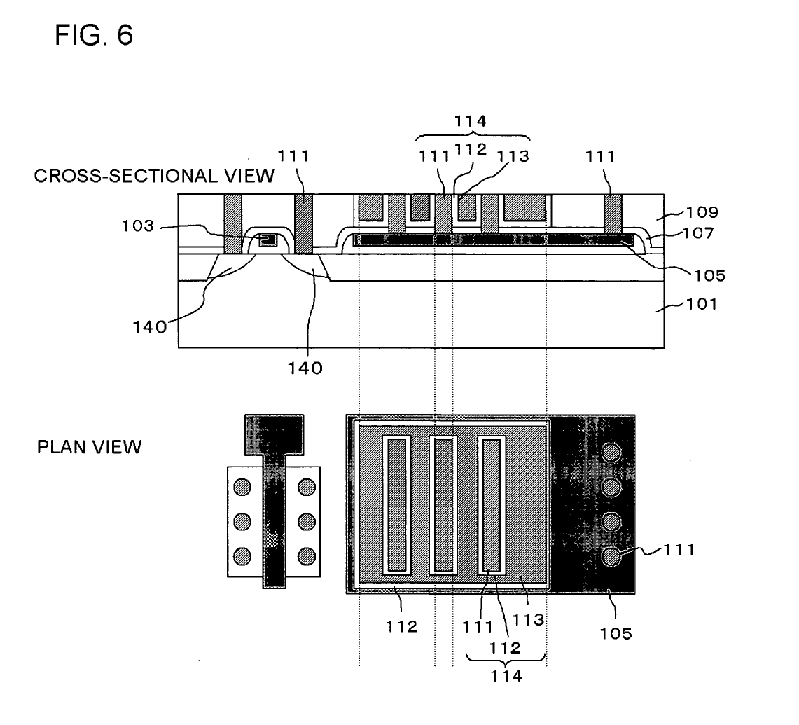

For instance, FIG. 6 is a view showing example of the other shapes of the capacitor element 114. FIG. 6 shows a state where the semiconductor device is manufactured up to a stage corresponding to FIG. 4G. Also in FIG. 6, like FIG. 4G, the upper drawing is a cross-sectional view, and lower drawing is a plan view.

In FIG. 6, a sectional shape of the connection plug 111 constituting the capacitor element 114 is a rectangle without corners. Also, in the configuration that such connection plug 111 with stripe shape is set to one conductor; it is possible to stably manufacture the capacitor element 114 inside the first insulating film 109.

In addition, configurations shown in FIG. 4G and FIG. 6 is one example of the shape of the capacitor element 114, and the shape of the capacitor element 114 and the shape of the connection plug 111 to be the component of the capacitor element 114 are not limited to the configurations. For instance, the connection plug 111 may suitably be a cylinder, an elliptical cylinder or a square column, and the stripe shaped columnar body. Further, shape of the connection plug 111 may suitably be a shape of frustum of circular cone or frustum of pyramid. In addition, when providing the capacitor element 114 inside the same layer as an interconnect formed layer, there may suitably be provided an opening with the same shape as an interconnect trench inside the first insulating film 109, followed by forming a metal film with the same shape as the interconnect in place of the connection plug 111. Also, in this case, it is possible to form the capacitor element 114 upon providing the capacitor film 112 and the metal film 113 in this order around the metal film with the same shape as the interconnect.

### Second Embodiment

In the semiconductor device 100 (FIG. 1) described in the first embodiment, there is adopted configuration in which the upper face of the connection plug 111 and the metal film 113 are positioned inside the same flat surface, however, also it is possible to adopt configuration in which the upper face of the metal film 113 is positioned lower than the upper face of the connection plug 111.

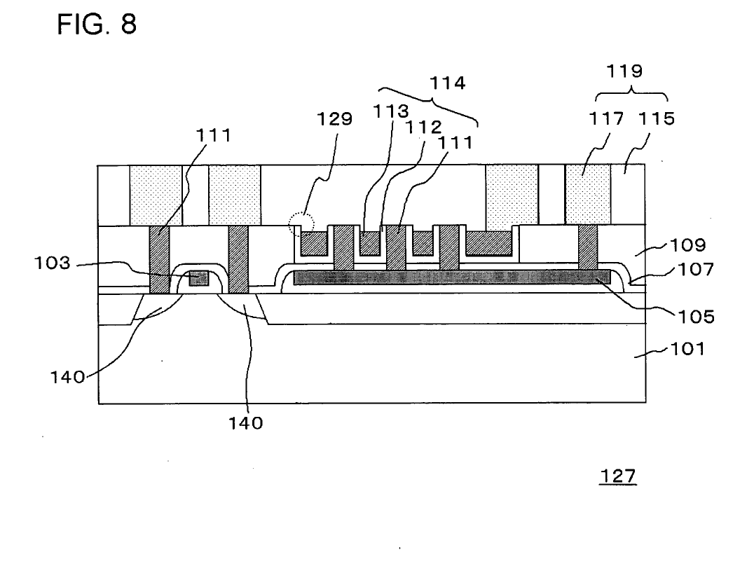

FIG. 8 is a cross-sectional view schematically showing configuration of the semiconductor device according to the present embodiment. Basic configuration of a semiconductor device 127 shown in FIG. 8 is the same as that of the semiconductor device 100 (FIG. 1), therefore, there will be described points different from the semiconductor device 100 mainly.

In the semiconductor device 127, upper faces of the first insulating film 109 and the connection plug 111 provided inside the first insulating film 109, and the capacitor film 112 reside in approximately the same face. And, the upper face of the metal film 113 is positioned lower than the upper face of the connection plug 111 in end portion of the metal film 113. For this reason, a recess 129 is formed in the vicinity of an upper end portion of the capacitor film 112. Also, in the semiconductor device 127, the upper face of the capacitor film 112 is coated with the second insulating film 115 or the interconnect 117.

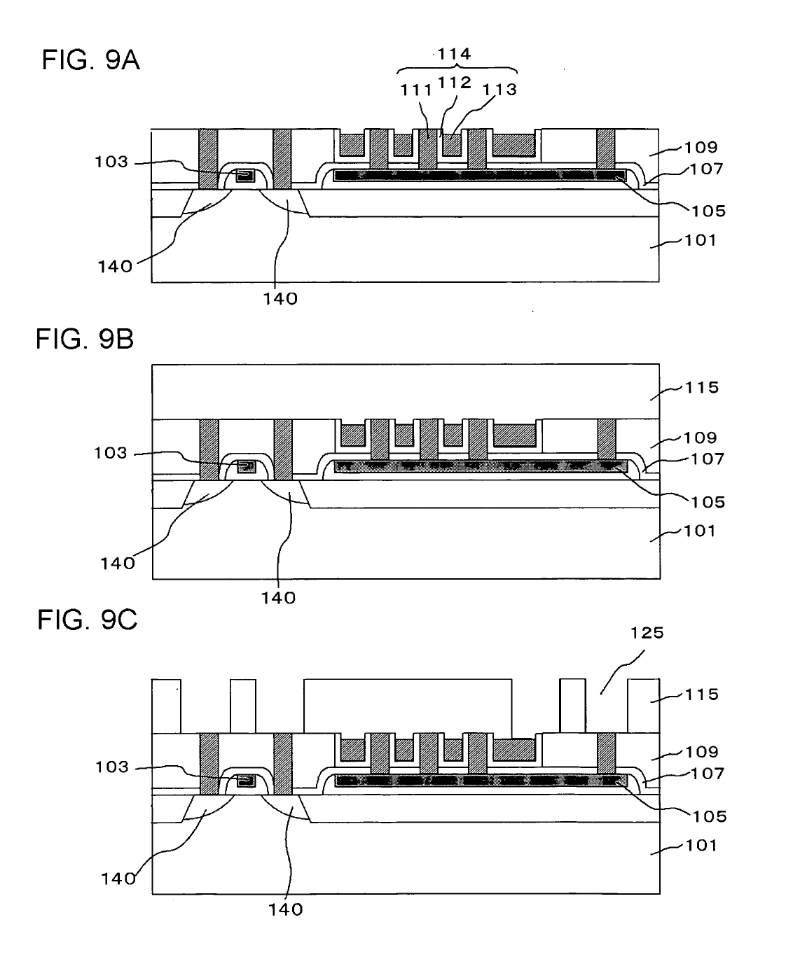

The semiconductor device 127 is manufactured with a following method. FIGS. 9A to 9C are cross-sectional views showing manufacturing process of the semiconductor device 127.

First, processes are performed up to the process of FIG. 3D while using the process described in the first embodiment. Next, an antireflection film and a photoresist are applied on the capacitor film 112 in this order, followed by forming a resist pattern to open the upper portion of the opening 123 while utilizing the photolithography technique. Then, like the formation of the connection plug 111, the barrier metal film and the Cu film are formed inside the opening 123 in this order, followed by embedding the opening 123 with the Cu film.

Then, the Cu film and the barrier metal film on the first insulating film 109 are removed by the CMP. At this time, polishing is performed until the upper face of the metal film 113 is positioned under the upper face of the connection plug 111 while selecting conditions of the CMP. Specifically, based on selection of a slurry, the polishing is performed in the condition that oxidation of a metal film takes place more preferentially than a mechanical polishing of the capacitor film 112. Owing to this, the recess 129 is formed. After the polishing, the metal film 113 is formed via the oxalic acid treatment and the pure water rinsing. Then, the capacitor film 112 is removed by the dry etching. Thereby, the first insulating film 109, and the upper faces of the connection plug 111 and capacitor film 112 are positioned in the same plane; and a layer in which the upper face of the metal film 113 is positioned under upper faces of the first insulating film 104, the connection plug 111 and the capacitor film 112 is formed (FIG. 9A).

Next, the second insulation film 115 is formed on the entire upper surface of the silicon substrate 101 while using the process described in the first embodiment (FIG. 9B). At this time, an upper portion of the metal film 113 is coated with an under face of the second insulating film 115 with the under face corresponding to the shape of the recess 129.

Then, an opening 125 is formed by the photoresist technique while using the process described in the first embodiment (FIG. 9C). Then, the interconnect 117 is formed upon embedding the opening 125 with the metal film. Also, the semiconductor device 127 has configuration where the upper face of the metal film 113 comes into contact with the under face of the interconnect 117, in the region in which the interconnect 117 is provided above the metal film 113. As a result, the semiconductor device 127 shown in FIG. 8 is obtained.

Successively, there will be described effects of the semiconductor device 127 shown in FIG. 8.

In the semiconductor device 127, the upper face of the metal film 113 is positioned under the upper face of the connection plug 111 in the end portion of the connection plug 111. By adopting such configuration that the recess 129 is provided, there is the effect that the connection plug 111 can be surely insulated from the metal film 113 by the capacitor film 112 in addition to the effect of the semiconductor device 100. Thereby, it is possible to further surely prevent leakage between the connection plug 111 and the capacitor element 114 formed inside the same layer. Consequently, it is possible to further improve reliability of the semiconductor device 127 with the capacitor element 114 residing.

In addition, the configuration of FIG. 8 can be obtained upon selecting the conditions of the CMP of the metal film 113. Thereby, the manufacturing the semiconductor device 127 is easy, resulting in configuration that is excellent in manufacturing stability.

As above, there is described the embodiment of the present invention while referring to the drawings, however, these are the illustrations of the present invention, therefore, it is also possible to adopt various constitution in addition to the above.

For instance, in the above embodiments, as for materials of the capacitor film 112, the high dielectric constant film (high-k film) such as Ta₂O₅, Al₂O₃, ZrOₓ, HfOₓ or HfSOₓ or the like may be used.

In addition, with regard to the barrier metal film, it is possible to use a refractory metal, such as, for instance, Ti, Ta or the like in addition to the W film. Specifically, for example, Ti, TiN, WN, Ta, TaN or the like are exemplified. In addition, a layered tantalum containing barrier metal film structure formed with TaN and Ta may be used. The barrier metal film can be formed by the method such as the sputtering technique, the CVD technique or the like.

In addition, as for the etching stopper film 107, it is possible to use various materials in addition to the above described SiCN. For instance, it is possible to use materials including nitrogen such as SiN, or SiON or the like.

It is apparent that the present invention is not limited to the above embodiment that modified and changed without departing from the scope and sprit of the invention.

1. A semiconductor device comprising:
a semiconductor substrate;
an insulating film provided on said semiconductor substrate;
a first conductor composed of a columnar body provided in said insulating film;
a second conductor provided around said first conductor and separated from a side surface of said first conductor; and
a capacitor film provided between said first conductor and said second conductor.

2. The semiconductor device according to claim 1, wherein said second conductor is composed of a conductive film embedded in said insulating film.

3. The semiconductor device according to claim 1, wherein said second conductor is provided on an etching stopper film, and said second conductor has a flat bottom face.

4. The semiconductor device according to claim 3, wherein said etching stopper film is formed so as to cover a side wall in the vicinity of a bottom portion of said first conductor.

5. The semiconductor device according to claim 1, wherein thickness of said capacitor film is approximately uniform.

6. The semiconductor device according to claim 1, wherein said first conductor and said second conductor are formed with the same material.

7. The semiconductor device according to claim 1, wherein said first conductor has a cylinder shape.

8. The semiconductor device according to claim 1, wherein an upper face of said first conductor and an upper face of said second conductor reside in the same plane.

9. The semiconductor device according to claim 1, wherein an upper face of said second conductor is positioned under an upper face of said first conductor on an end portion of said second semiconductor.

10. The semiconductor device according to claim 1, wherein plural capacitor elements composed of said first conductor, said second conductor and said capacitor film are provided in said insulating film.

11. The semiconductor device according to claim 10, wherein there is a lower electrode provided in such a way as to come into contact with a bottom portion of a plurality of said first conductors.

12. A method for manufacturing a semiconductor device, comprising:
forming a lower electrode on a semiconductor substrate;
forming an insulating film on said lower electrode;
forming a columnar connection hole, which reaches an upper face of said lower electrode while selectively removing said insulating film;
forming a first metal film so as to embed said connection hole;
obtaining a first conductor while removing said metal film formed on outside said connection hole;
forming a concave portion while removing said insulating film around said first conductor and exposing at least a part of a side wall of said first conductor;
forming a capacitor film covering said side wall so as to embed said part of said concave portion;
forming a second metal film so as to embed said concave portion after said forming said capacitor film; and
obtaining a second conductor while removing said second metal film formed on outside said concave portion.

13. A method for manufacturing a semiconductor device, comprising:
forming a transistor with gate electrode and a diffusion region at a first element region on a semiconductor substrate;
forming a lower electrode at a second element region on said semiconductor substrate;
forming an insulating film to cover said transistor and said lower electrode;
forming a first connection hole and a second connection hole in said insulating film simultaneously, said first connection hole exposing said diffusion region therein and said second connection hole exposing said lower electrode therein;
filling said first connection hole and said second connection hole with a first conductive material simultaneously to form a connection plug on said diffusion region and a first conductor at said second element region;
forming a concave portion while removing said insulating film around said first conductor to expose at least a part of a side wall of said first conductor;
forming a capacitor film covering said side wall;
forming a second conductive material on said capacitor film to fill said concave portion and to form a second conductor composing a capacitor together with said lower electrode, said first conductor and said capacitor film.

14. The method for manufacturing the semiconductor device according to claim 12, further comprising:
forming an etching stopper film on said lower electrode, after said forming said lower electrode and before said forming said insulating film.

15. The method for manufacturing the semiconductor device according to claim 13, further comprising:
forming an etching stopper film on said lower electrode, after said forming said lower electrode and before said forming said insulating film.

16. The method for manufacturing the semiconductor device according to claim 12, wherein said first metal film and said second metal film are copper containing metal films.

17. The method for manufacturing the semiconductor device according to claim 13, wherein said first conductive material and said second conductive material are copper containing metal films.
